(19) United States
(12) Patent Application Publication
(10) Pub. No.: US 2025/0378865 A1
(43) Pub. Date: Dec. 11, 2025

(54) RESERVOIR COMPUTER AND CONTROL METHOD THEREOF

(71) Applicant: Renesas Electronics Corporation, Tokyo (JP)

(72) Inventors: Kohei HASHIMOTO, Tokyo (JP); Yohei SATO, Tokyo (JP); Hirofumi HEBISHIMA, Tokyo (JP); Toshiaki MORIOKA, Tokyo (JP)

(21) Appl. No.: 19/217,108

(22) Filed: May 23, 2025

(30) Foreign Application Priority Data
Jun. 10, 2024 (JP) 2024-093493

(51) Int. Cl. G11C 11/22

(52) U.S. Cl. CPC G11C 11/2297; G11C 11/223; G11C 11/2273; G11C 11/2293

(57) ABSTRACT

Control the period during which voltage is applied to the drain to provide a reservoir computer with low power consumption. A reservoir computer is provided, comprising an FeFET with a drain connected to a sense circuit that applies a drain voltage and detects the drain current by converting it from analog to digital. The gate electrode is connected to a gate voltage generation circuit that inputs a gate voltage in the form of a triangular wave with peaks of positive and negative voltages. Additionally, it includes a first switch positioned between the sense circuit and the drain. The gate voltage generation circuit comprises a charge pump circuit for applying positive voltage, a charge pump circuit for applying negative voltage, a pulse generation circuit, and a Vref regulator.

### CROSS-REFERENCE TO RELATED APPLICATIONS

The disclosure of Japanese Patent Application No. 2024-093493 filed on Jun. 10, 2024, including the specification, drawings and abstract is incorporated herein by reference in its entirety.

### BACKGROUND

The present invention relates to a reservoir computer and a control method for a reservoir computer.

There are disclosed techniques listed below.

### [Patent Document 1] Japanese Unexamined Patent Application Publication No. 2023-161307

Patent Document 1 discloses a semiconductor device equipped with a ferroelectric memory cell.

### SUMMARY

However, the related semiconductor device applies a constant voltage to the drain for reading, resulting in high power consumption. Therefore, the purpose of this disclosure is to provide a reservoir computer with low power consumption by controlling the period during which voltage is applied to the drain.

Other objects and novel features will become apparent from the description of this specification and the accompanying drawings.

According to one embodiment, the reservoir computer includes a first switch disposed between the sense circuit and the drain.

According to the above-mentioned embodiment, it is possible to provide a reservoir computer with low power consumption by controlling the period during which voltage is applied to the drain.

### BRIEF DESCRIPTION OF THE DRAWINGS

FIG. 1 is a diagram showing the change of state of a reservoir computer according to the embodiment.

FIG. 2 is a diagram showing the changes in input (Vg), drain voltage (Vd), and read current (Id) of the related reservoir computer.

FIG. 3 is a diagram showing the changes in input (Vg), drain voltage (Vd), and read current (Id) of the related reservoir computer.

FIG. 4 is a schematic diagram of a circuit constituting the reservoir computer according to the first embodiment.

FIG. 5 is a diagram explaining the gate voltage generation circuit of the reservoir computer according to the first embodiment.

FIG. 6 is a diagram showing the application timing of the drain voltage of the reservoir computer according to the first embodiment.

FIG. 7 is a diagram showing the application timing of the drain voltage when reading the reservoir computer according to the second embodiment multiple times.

FIG. 8 is a diagram showing the timing of applying gate voltage multiple times to the reservoir computer according to the third embodiment.

FIG. 9 is a schematic diagram of a circuit constituting the reservoir computer according to the third embodiment.

### DETAILED DESCRIPTION

For clarity of explanation, the following description and drawings are appropriately omitted and simplified. Also, each element described in the drawings as a functional block for performing various processes can be configured by hardware such as a CPU (Central Processing Unit), memory, and other circuits, and can be implemented by software such as a program loaded into memory. Therefore, these functional blocks can be realized by hardware, software operating on hardware, or a combination thereof. In the drawings, the same elements are denoted by the same reference numerals, and a repetitive description thereof is omitted as necessary.

Also, the programs described above may be stored and provided to a computer using various types of non-transitory computer readable media. Non-transitory computer readable media include various types of tangible storage media. Examples of non-transitory computer-readable media include magnetic recording media (e.g., flexible disks, magnetic tapes, hard disk drives), magneto-optical recording media (e.g., magneto-optical disks), CD-ROM (Read Only Memory, a CD-R, a CD-R/W, solid-state memories (e.g., masked ROM, PROM (Programmable ROM), EPROM (Erasable PROM, flash ROM, RAM (Random Access Memory)). The programs may also be supplied to the computer by various types of transitory computer-readable media. Examples of transitory computer-readable media include electrical signals, optical signals, and electromagnetic waves. The transitory computer readable medium may provide the program to the computer via wired or wireless communication paths, such as electrical wires and optical fibers.

### Description of the Reservoir Computer and Issues According to the Embodiment

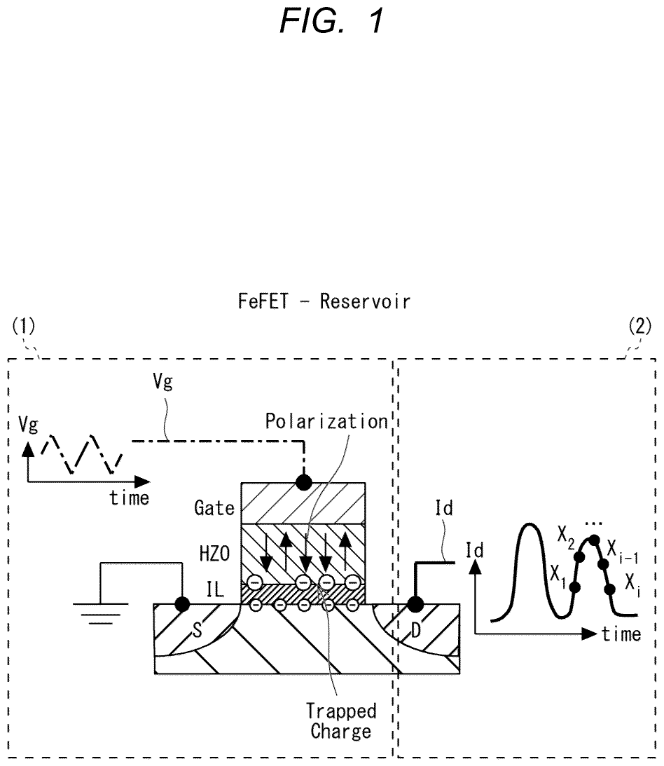

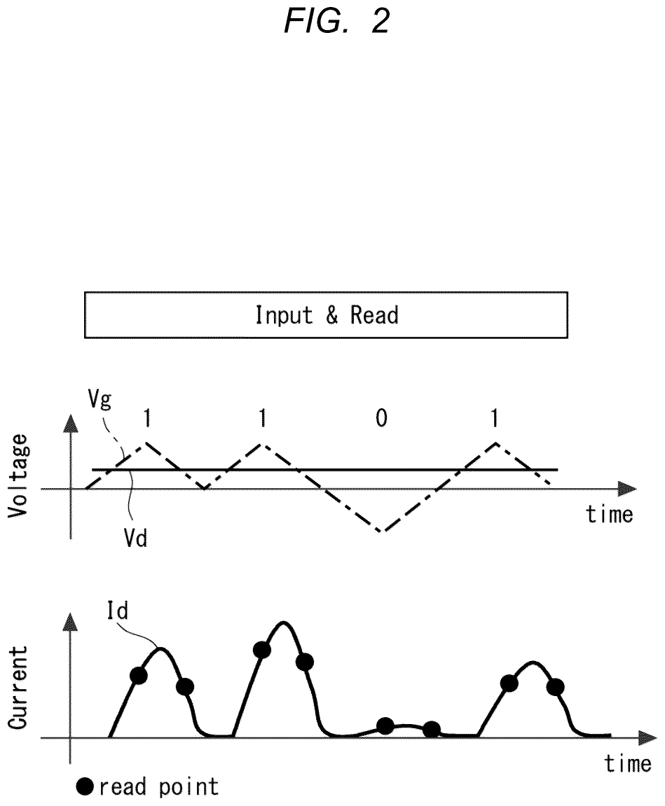

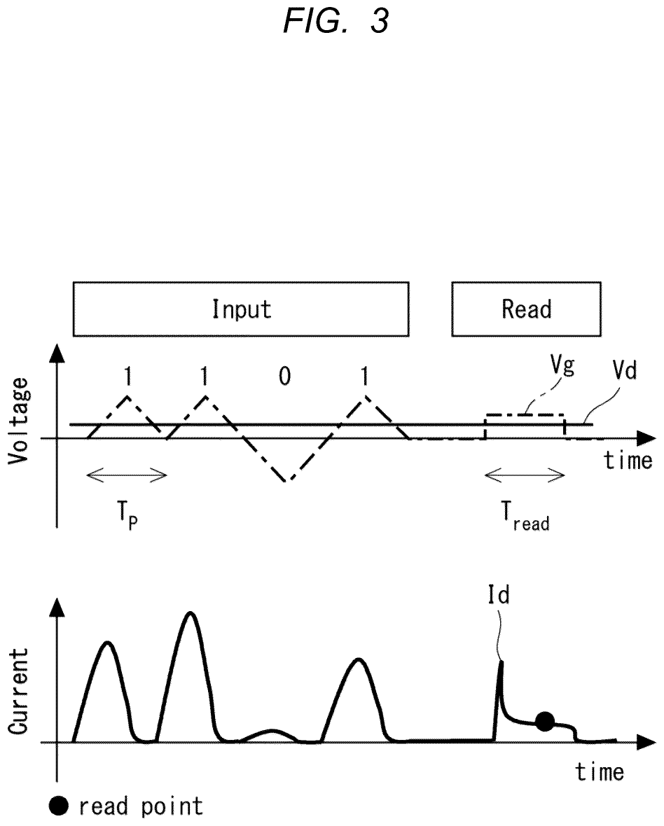

FIG. 1 is a diagram showing the change of state of a reservoir computer according to the embodiment. FIG. 2 is a diagram showing the changes in input (Vg), drain voltage (Vd), and read current (Id) of the related reservoir computer. FIG. 3 is a diagram showing the changes in input (Vg), drain voltage (Vd), and read current (Id) of the related reservoir computer. Referring to FIGS. 1 to 3, the reservoir computer and issues according to the embodiment will be described.

As shown in FIG. 1, the semiconductor device constituting the reservoir computer according to the embodiment includes a source, a drain, a back, and a gate. The semiconductor device is also called a FeFET (Ferroelectric Field Effect Transistor). The source and drain are formed in the semiconductor layer. The back is formed between the source and the drain. The back is, for example, a P-type well region. The back is at the same potential as the source. Between the gate electrode and the semiconductor layer, there is an intermediate layer (Inter layer (IL)) formed from a paraelectric film and a ferroelectric film. The ferroelectric film is a charge storage layer. The ferroelectric film preferably includes HZO (Hafnium Zirconium Oxide) having Al (Aluminum) or AlN (Aluminum Nitride). The HZO film is a ferroelectric film. By doping the HZO film with Al or AlN, a ferroelectric film with a larger polarization capacity is produced.

Such a FeFET is characterized by a long retention time. Therefore, if the FeFET has a longer retention time than the related FeFET, the circuit and control method of this disclosure can be applied.

The source is grounded. For example, by inputting the input Vg, which is input data, to the gate electrode and applying voltage to the drain, the drain current Id between the source and drain in the reservoir state is detected. Here, the input Vg is the number of times the gate voltage is input. The reservoir state changes according to the polarization state and charge trap state of the FeFET. Due to this polarization state and charge trap state, the drain current shows hysteresis with respect to the gate voltage and does not change linearly. Therefore, the FeFET has a memory function. The FeFET indicates reservoir states X1, X2, Xi-1, Xi, for example, by the drain current Id.

The reservoir computation is performed in two steps: (1) updating the reservoir state by input (change in polarization state and charge trap state), and (2) outputting the reservoir state (output of drain current).

FIG. 2 is a diagram showing an example of sequential reading. When the gate voltage Vg is applied, the sequential drain current Id is detected. Sequential reading results in a large consumption current because (1) and (2) are performed simultaneously, always allowing the drain current to flow.

FIG. 3 is an example of multiple inputs and a single readout. Even if (1) and (2) are simply separated, the drain current always flows, resulting in high power consumption.

### Description of the Reservoir Computer According to the First Embodiment

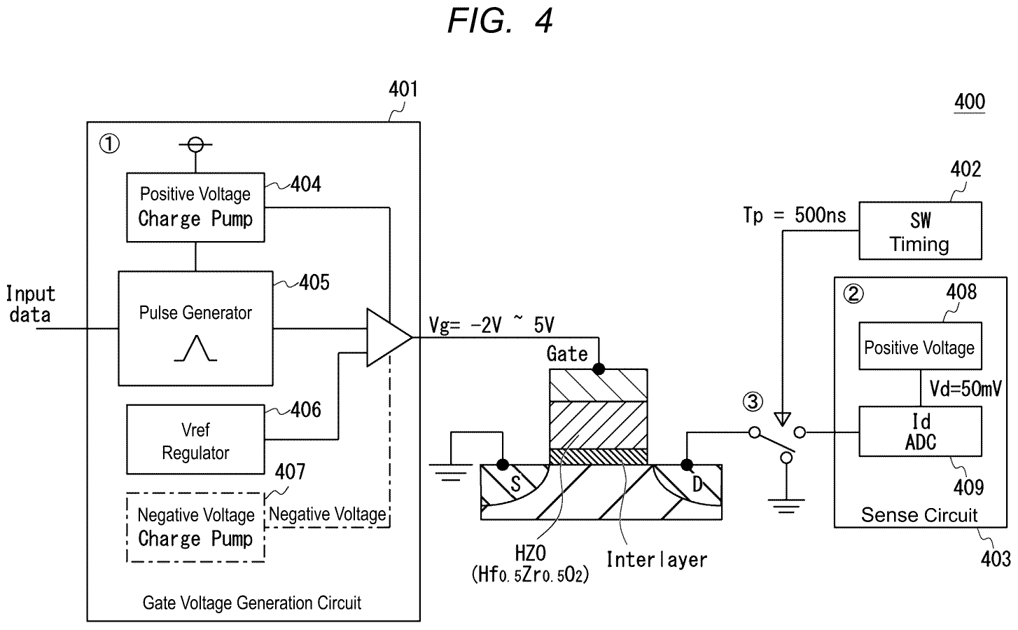

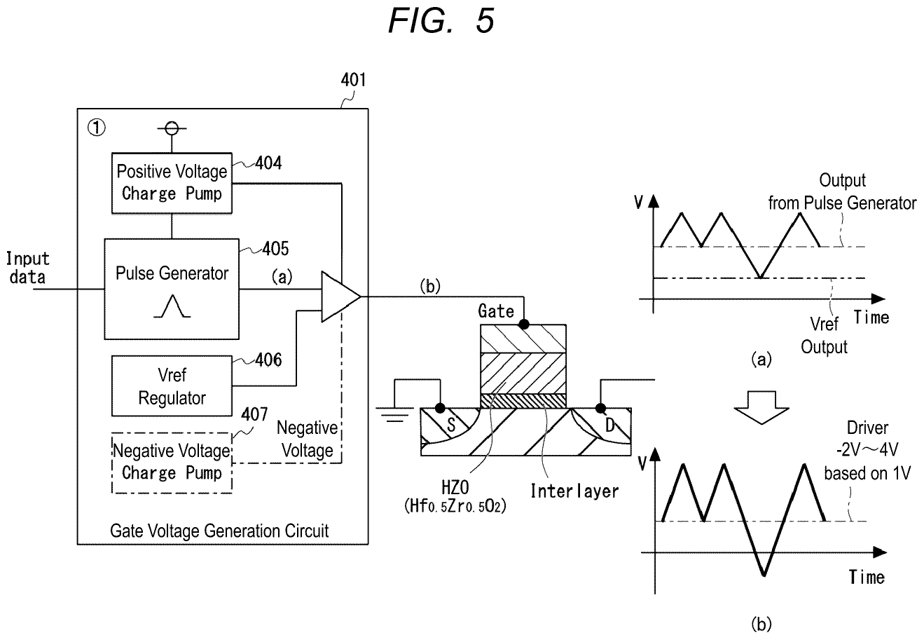

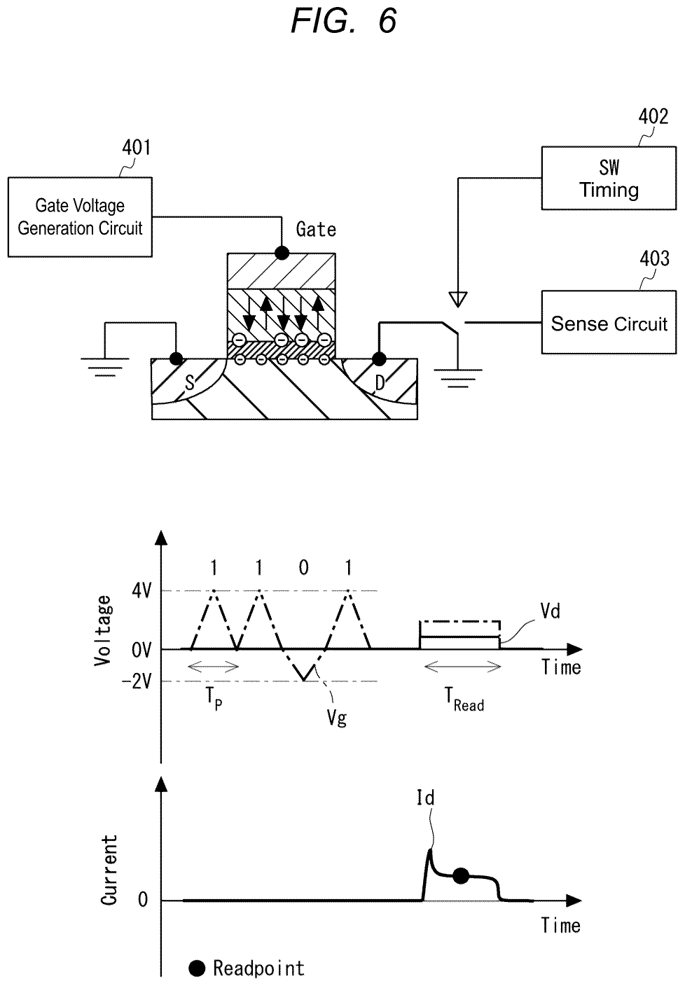

FIG. 4 is a schematic diagram of a circuit constituting the reservoir computer according to the first embodiment. FIG. 5 is a diagram explaining the gate voltage generation circuit of the reservoir computer according to the first embodiment. FIG. 6 is a diagram showing the application timing of the drain voltage of the reservoir computer according to the first embodiment. Referring to FIGS. 4 to 6, the reservoir computer according to the first embodiment will be described.

As shown in FIG. 4, the reservoir computer 400 according to the first embodiment includes a gate voltage generation circuit 401, a switch timing circuit 402, and a sense circuit 403. A first switch is disposed between the drain and the sense circuit 403. The switch timing circuit 402 is connected to the first switch and controls the first switch. The switch timing circuit is switched, for example, at a cycle of 500 ns. The sense circuit 403 includes a circuit 408 that applies a positive voltage Vd to the drain and a circuit 409 that converts the drain current Id to analog digital. The positive voltage is, for example, 50 mV. The sense circuit 403 detects the drain current Id.

As shown in FIG. 5, the gate voltage generation circuit 401 includes a charge pump circuit 404 that applies a positive voltage, a pulse generator 405, a Vref regulator 406, and a charge pump circuit 407 that applies a negative voltage. The Vref regulator has the function of adjusting the reference voltage Vref.

As shown in the right diagram (a) of FIG. 5, when data is input, the pulse generator 405 generates a triangular wave pulse. As shown in the right diagram (b) of FIG. 5, when the charge pump circuit 404 that applies a positive voltage to the triangular wave output from the pulse generator 405, the pulse generator 405, the Vref regulator 406, and the charge pump circuit 407 that applies a negative voltage act, the desired gate voltage is obtained. The desired gate voltage is a triangular wave with peaks of positive and negative voltages. The desired gate voltage is, for example, a triangular wave with a maximum value of 4 V and a minimum value of −2 V, based on 1 V.

As shown in the upper diagram of FIG. 6, the reservoir computer according to the first embodiment can adjust the detection timing of the drain current Id of the sense circuit by including the switch timing circuit 402. As shown in the lower diagram of FIG. 6, for example, the gate voltage Vg is applied multiple times at a cycle Tp. The voltage Vd is applied to the drain at the readout cycle TRead. Then, the drain current Id is read at the readout point (Readpoint).

In this way, during data input, the switch of the drain is switched to the ground potential, and the state of the reservoir is updated without flowing the drain current. When reading the state of the reservoir, the switch of the drain is switched to read the drain current.

With the above configuration, the period of applying voltage to the drain is controlled, and a reservoir computer with low power consumption can be provided.

### Description of the Reservoir Computer According to the Second Embodiment

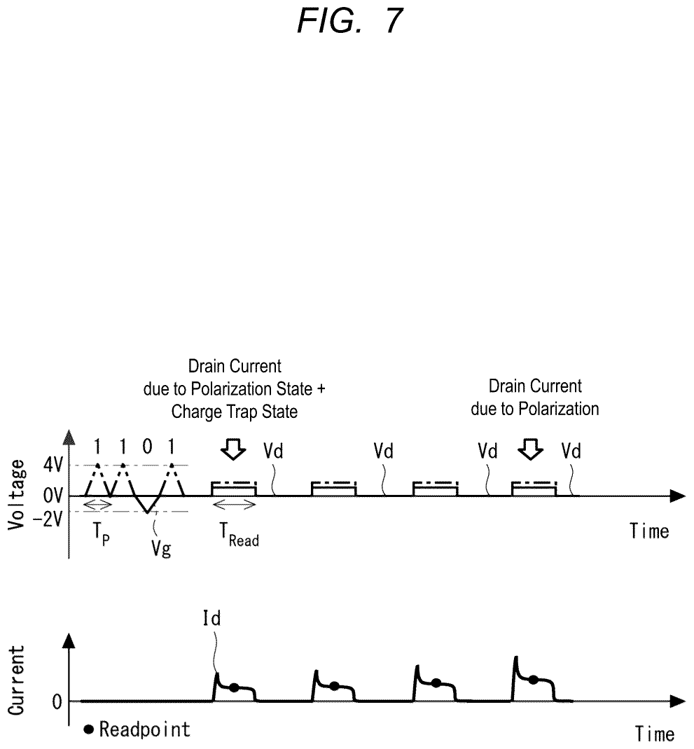

FIG. 7 is a diagram showing the application timing of the drain voltage when reading the reservoir computer according to the second embodiment multiple times. The reservoir computer according to the second embodiment will be described with reference to FIG. 7. The reservoir computer according to the second embodiment differs in that it performs multiple readings compared to the reservoir computer according to the first embodiment.

As shown in FIG. 7, for example, the gate voltage Vg is applied multiple times at a cycle Tp. The voltage Vd is applied multiple times to the drain at the readout cycle TRead. Then, Id is read at multiple readout points (Readpoint). That is, the reservoir computer inputs the gate voltage to the gate electrode and then applies voltage multiple times to the drain without additional input to read the state of the reservoir. At these multiple readout points, the drain current Id changes over time from the drain current due to the polarization state+charge trap state to the drain current due to polarization. 0001

By utilizing such a state, the amount of information obtained from one set of inputs to the reservoir can be increased. Therefore, the amount of information can be increased without increasing the number of FeFETs, allowing for improved recognition accuracy with low power consumption.

### Description of the Reservoir Computer According to the Third Embodiment

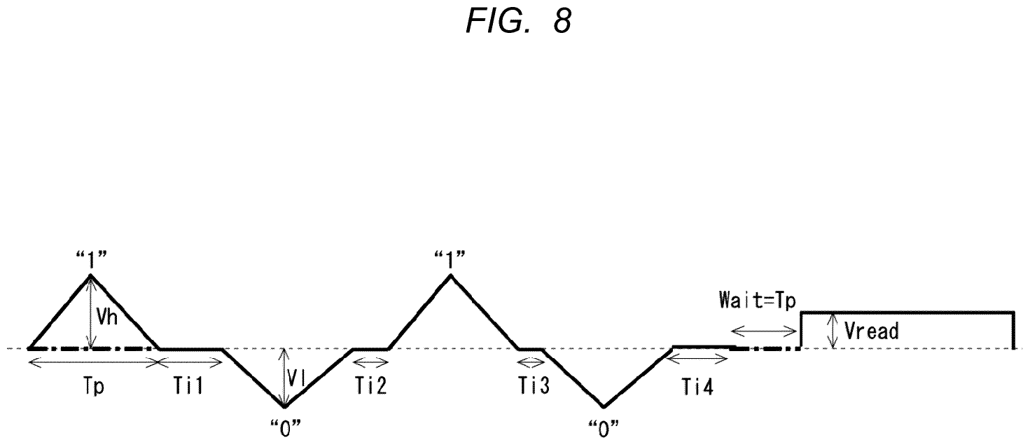

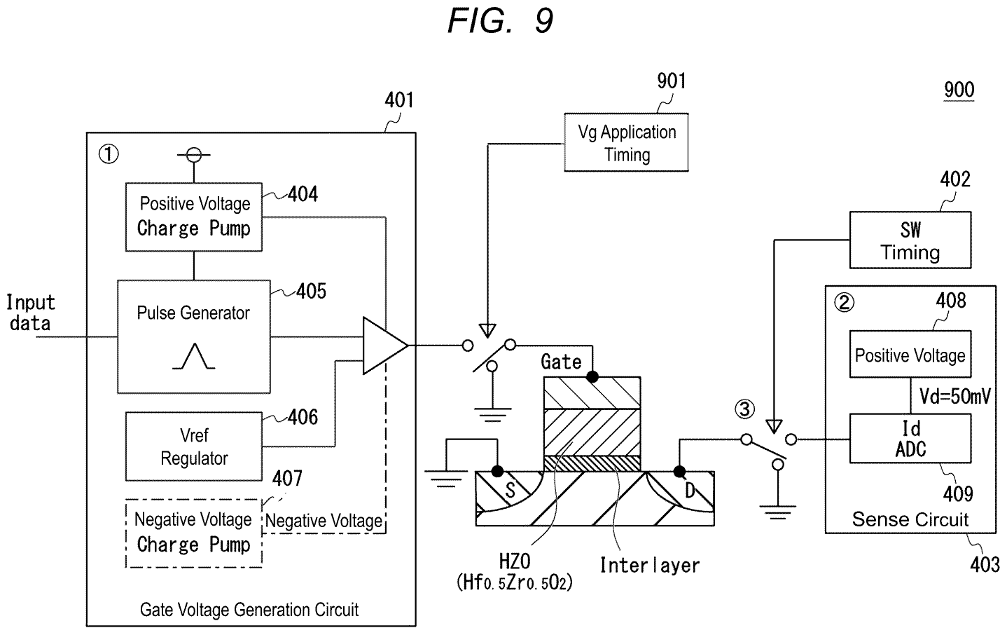

FIG. 8 is a diagram showing the timing when applying the gate voltage multiple times to the reservoir computer according to the third embodiment. FIG. 9 is a schematic diagram of the circuit constituting the reservoir computer according to the third embodiment. The reservoir computer according to the third embodiment will be described with reference to FIGS. 8 and 9. The reservoir computer according to the third embodiment differs from the reservoir computer according to the first embodiment in that it provides intervals in the input of the gate voltage.

As shown in FIG. 8, the control method of the reservoir computer according to the third embodiment includes intervals Ti1, Ti2, Ti3, and Ti4 between inputs when inputting to the FeFET. Ti1, Ti2, Ti3, and Ti4 may be the same or different periods. That is, the control method of the reservoir computer according to the third embodiment updates the state of the FeFET reservoir by inputting the gate voltage multiple times and changes the time between multiple inputs of the gate voltage. The control method of the reservoir computer according to the third embodiment utilizes the transient response of the FeFET, such as the relaxation of the polarization state and the detrapping of charges occurring during this interval, in reservoir computing. As a result, the nonlinearity of the FeFET response is improved, thereby improving the performance of the reservoir.

Also, the control method of the reservoir computer according to the third embodiment allows the interval time to change, so that in addition to inputs “1” and “0”, Ti1, Ti2, Ti3, and Ti4 can also be input information. Therefore, the control method of the reservoir computer according to the third embodiment can input analog data and multi-bit data.

As shown in FIG. 9, the reservoir computer 900 according to the third embodiment includes a gate voltage generation circuit 401, a switch timing circuit 402, a sense circuit 403, and a gate voltage application timing circuit 901. A second switch is disposed between the gate voltage generation circuit 401 and the gate electrode. The second switch is controlled by the gate voltage application timing circuit 901.

The gate voltage application timing circuit 901 controls the application timing of the gate voltage Vg. Therefore, the gate voltage application timing circuit 901 can control the intervals Ti1, Ti2, and Ti3.

Each embodiment can be combined with each other. That is, the second embodiment and the third embodiment may be combined.

Although the invention made by the inventor has been specifically described based on the embodiment, the present invention is not limited to the embodiment already described, and it is needless to say that various modifications can be made without departing from the gist thereof.

What is claimed is:

1. A reservoir computer comprising:
an FeFET (Ferroelectric Field Effect Transistor);
a gate voltage generating circuit configured to output a triangular wave with peaks of positive and negative voltages to a gate electrode of the FeFET;
a sensing circuit configured to connect to a drain electrode of the FeFET, and configured to apply a drain voltage and detect a drain current by performing analog-digital conversion; and
a first switch coupled between the sense circuit and the drain.

2. The reservoir computer according to claim 1, wherein the gate voltage generation circuit includes a first charge pump circuit that generates the positive voltage, a second charge pump circuit that generates the negative voltage, a pulse generator, and a reference voltage generator.

3. The reservoir computer according to claim 1,
wherein the gate voltage generation circuit is configured to repeatedly apply the gate voltage to update the state of the FeFET reservoir,
wherein, while updating the state of the sensing circuit, the first switch cuts off the drain voltage the drain electrode, and
wherein, when the state of the reservoir is read, the first switch applies the drain voltage to the drain electrode.

4. The reservoir computer according to claim 3, further configured to, after the gate voltage generation circuit applies the gate voltage to the gate electrode, repeatedly apply the drain voltage to the drain electrode without any additional application of the gate voltage to read the state of the reservoir.

5. The reservoir computer according to claim 1, further comprising a second switch coupled between the gate electrode and the gate voltage generation circuit.

6. The reservoir computer according to claim 3,
wherein the gate voltage generation circuit is further configured to vary the time interval 1 of the repeatedly application of the gate voltage.

7. The reservoir computer according to claim 1, wherein the FeFET uses HZO (hafnium zirconium oxide) with Al or AlN in the charge storage layer.

8. A control method for a reservoir computer, comprising:
applying a gate voltage that has a triangular wave with positive and negative voltage peaks to a gate electrode of an FeFET (Ferroelectric Field Effect Transistor;
applying a drain voltage to a drain electrode of the FeFET; and
detecting a drain current of the FeFET by analog-to-digital conversion.

9. The control method for a reservoir computer according to claim 8, wherein the gate voltage is generated by a positive voltage charge pump circuit and a negative voltage charge pump circuit.

10. The control method for a reservoir computer according to claim 8, further comprising:
updating the state of the reservoir by repeatedly applying the gate voltage to the gate electrode;
cutting off the drain voltage to the drain electrode while updating the state of the reservoir; and
applying the drain voltage to the drain electrode when reading the state of the reservoir.

11. The control method for a reservoir computer according to claim 10, further comprises:
after the gate voltage generation circuit applies the gate voltage to the gate electrode, repeatedly apply the drain voltage to the drain electrode without any additional application of the gate voltage to read the state of the reservoir.

12. The control method for a reservoir computer according to claim 8, further comprising:
cutting off the gate voltage to the gate electrode.

13. The control method for a reservoir computer according to claim 10, further comprising:
varying the time interval of the repeatedly application of the gate voltage.

14. The control method for a reservoir computer according to claim 8, wherein the FeFET uses HZO (hafnium zirconium oxide) having Al or AIN in the charge storage layer.
